(19) United States
(12) Patent Application Publication
(10) Pub. No.: US 2004/0029394 A1
(43) Pub. Date: Feb. 12, 2004

(54) Method and structure for preventing wafer edge defocus

(75) Inventor: Yuan-Hsun Wu, Jungli City (TW)

Correspondence Address: MERCHANT & GOULD PC, P.O. BOX 2903, MINNEAPOLIS, MN, 55402-0903, US

(73) Assignee: NANYA TECHNOLOGY CORPORATION, Taoyuan (TW)

(21) Appl. No.: 10/313,602

(22) Filed: Dec. 5, 2002

(30) Foreign Application Priority Data
Aug. 12, 2002 (TW) 91118072

(51) Int. Cl. H01L 21/302; H01L 21/461

(52) U.S. Cl. 438/745

(57) ABSTRACT

A method and a structure for preventing wafer edge defocus. The method comprises the following steps. First, a wafer is provided. Next, an anti-reflect layer is formed on the wafer. Parts of the anti-reflect layer are removed to expose the rim of the wafer surface. Finally, a photoresist layer is blanketed on the anti-reflect layer and the rim of the wafer.

### BACKGROUND OF THE INVENTION

1. Field of the Invention

The present invention relates in general to semiconductor manufacturing, and particularly to photolithography.

2. Description of the Related Art

Photolithography comprising priming, photoresist coating, baking, exposure, post bake, and development, is used to transfer specific patterns onto semiconductor devices or integrated circuits during the fabrication process. A masking step transfers the pattern of a photomask onto a photoresist layer on the device surface by exposing the photoresist through the mask. Selected areas of the photoresist, based on the pattern of the mask, are then etched so that subsequent process steps, such as impurity introduction, oxidation, and metallization, can be performed. A semiconductor device with the desired electrical properties is then obtained after several of the photolithography and etching steps. The critical factor of the yield of the semiconductor devices depends on the photolithography.

The difficulty of controlling the uniformity of the thickness of photoresist formed by spin coating is well known. In spin coating, the photoresist applied on the surface of the center is spread by spinning the wafer. Thus, the spread photoresistor is non-uniform, resulting in thicker photoresist at the wafer edge and thinner at the center.

Additionally, the accuracy of the thickness of the wafer measured by a conventional exposure apparatus is not good. The divisions of wafer surface are separately measured by six detectors of the conventional exposure apparatus, as shown in FIG. 1. The average thickness of the division is then calculated from the six measurements. However, the divisions of the wafer edge are not contained completely, such that the accuracy of the thickness of the wafer edge is not as accurate as that of the center wafer because the number of the measured data is less than six. Therefore, the wafer edge is usually given up due to the reduction of the available area of the wafer.

### SUMMARY OF THE INVENTION

Accordingly, an object of the invention is to provide a method for preventing wafer edge from defocus that produces a flat surface of the wafer edge.

Another object of the invention is to provide a method for preventing wafer edge defocus, enhancing the depth of the focus (DOF) of the wafer edge and enlarge the critical dimension (CD).

A further object of the invention is to provide a method for preventing wafer edge defocus, thereby increasing the available area.

The method comprises the following steps. First, a wafer is provided. Next, an anti-reflect layer is formed on the wafer. Parts of the anti-reflect layer are removed to expose the rim of the wafer surface. Finally, a photoresist layer is blanketed on the anti-reflect layer and the rim of the wafer.

The anti-reflect layer comprising an organic anti-reflection coating (organic ARC), an inorganic anti-reflection coating (inorganic ARC), a dielectric anti-reflection coating (dielectric ARC), a plasma enhanced anti-reflective layer (PEARL), or a combination thereof, can be a bottom anti-reflect layer (BARC) . The anti-reflect layer can be formed by deposition or spin coating. Parts of the anti-reflect layer can be removed by edge cleaning as is known. The photoresist layer can be formed by spin coating.

According to the aspect of the present invention, it is also an object to provide a structure for preventing wafer edge defocus.

The structure comprises a wafer, an anti-reflect layer installed on parts of the wafer such that the rim of the wafer are exposed, and a photoresist layer blanketing the anti-reflect layer and the rim of the wafer.

### BRIEF DESCRIPTION OF THE DRAWINGS

The present invention can be more fully understood by reading the subsequent detailed description and examples with references made to the accompanying drawings, wherein:

FIG. 1 is a schematic drawing illustrating the division of the wafer into squares which are subsequently exposed by the conventional exposure apparatus;

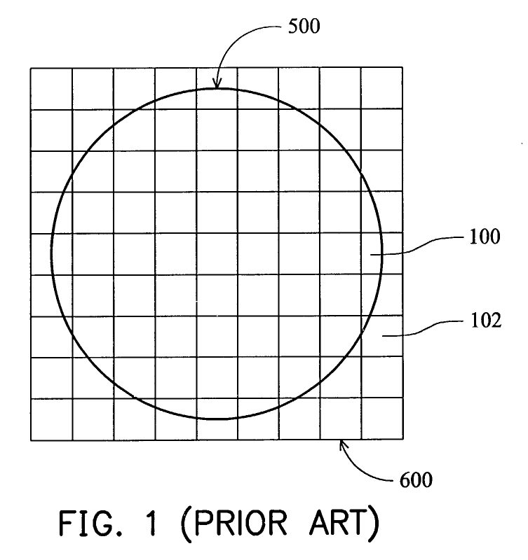

FIGS. 2A to 2D are schematic cross-sections illustrating the steps according to the preferred embodiment of the invention;

FIG. 3 is a schematic drawing illustrating the different depths of focus (DOF) of the wafer edge (indicated by “A”) and the center (indicated by “A”) under different critical dimensions (CD) according to the preferred embodiment of the invention;

### DETAILED DESCRIPTION OF THE INVENTION

There will now be described an embodiment of this invention with reference to the accompanying drawings.

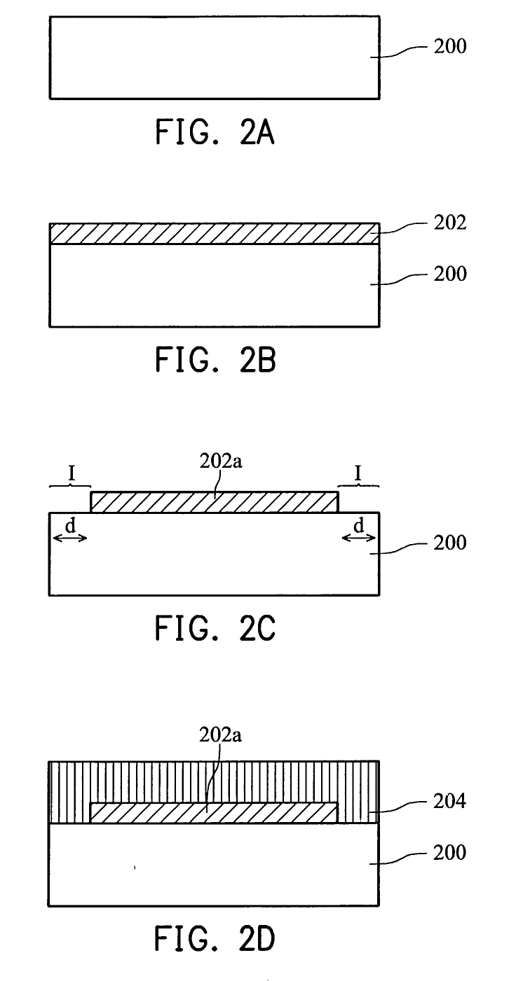

First, a wafer 200, which may comprise a transistor, a diode, or any other conventional semiconductor device, is provided, as shown in FIG. 2A.

Next, as shown in FIG. 2B, an anti-reflect layer 202, the bottom anti-reflect layer (BARC), is formed on the wafer 200. The anti-reflect layer 202 comprising an organic anti-reflection coating (organic ARC), an inorganic anti-reflection coating (inorganic ARC), a dielectric anti-reflection coating (dielectric ARC), a plasma enhanced anti-reflective layer (PEARL), or a combination thereof. The anti-reflect layer can be formed by deposition or spin coating. For example, the organic ARC is preferably formed by spin coating, and the inorganic ARC, dielectric ARC, and PEARL are all preferably formed by chemical vapor deposition (CVD). The thickness of the anti-reflect layer 202 is about 80˜150 μm, wherein 90˜135 μm is preferable.

As shown in FIG. 2C, parts “I” of the anti-reflect layer 202 with a width “d” are preferably removed to expose the rim of the wafer 200 surface by edge cleaning process as is known. The width “d” is about 0.5˜3 mm, wherein 1˜2.5 mm is preferable.

Finally, a photoresist layer 204 is blanketed on the whole wafer to cover the anti-reflect layer 202a and the rim of the wafer “I” , as shown in FIG. 2D. The photoresist layer 204 is preferably formed by spin coating, spreading the photoresistor applied on the surface of the center by spinning. The spread photoresistor is non-uniform, resulting in uneven thickness of photoresistor at wafer edge compared to the center. According to the present invention, the parts “I” of the anti-reflect layer 202 on the wafer edge are removed before forming the photoresist layer 204, rendering the thickness of the wafer uniform from center to edge.

According to the present invention, the structure for preventing wafer edge defocus comprises a wafer 200, an anti-reflect layer 202a installed on parts of the wafer 200 such that parts “I” of the wafer 200 are exposed, and a photoresist layer 204 blankets the anti-reflect layer 202a and the rim of the wafer “I”.

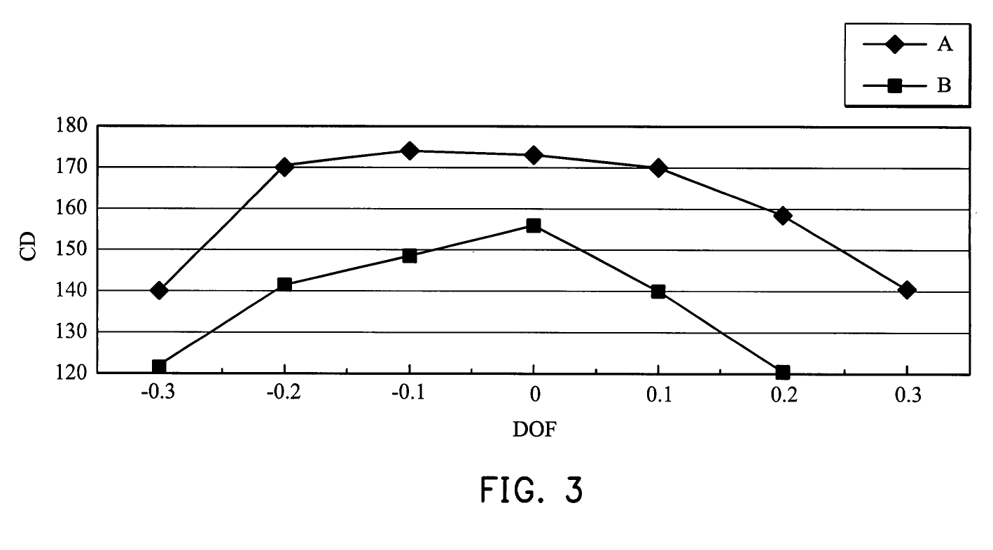

In FIG. 3, the depth of focus (DOF) of the structure of the present invention under different critical dimension (CD) is shown. In curve A, showing DOF of the wafer edge without anti-reflect layer, DOF is about 0.6 μm when CD is about 140 nm. In curve B, showing DOF of the center having anti-reflect layer thereon, DOF is about 0.3 μm when CD is about 140 nm. As well, the CD of the wafer edge increases with the increasing exposure energy absorbed in the wafer edge, resulting from absence of the anti-reflect layer 204 on the wafer edge.

The present invention provides several advantages. First, the CD of the wafer edge increases with the increasing exposure energy absorbed in the wafer edge, resulting from absence of the anti-reflect layer 204 on the wafer edge. Second, a flat surface is produced, to avoid variations in the surface thickness of the wafer edge, increasing DOF. Third, the available area of the wafer is increased. Fourth, parts of the anti-reflect layer 204 are preferably removed by normal manufacture edge cleaning without requiring any extra process.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for preventing wafer edge defocus, comprising:
providing a wafer;
forming an anti-reflect layer on the wafer;
removing parts of the anti-reflect layer to expose the rim of the wafer surface; and
blanketing a photoresist layer on the anti-reflect layer and the rim of the wafer.

2. The method as claimed in claim 1, wherein the anti-reflect layer comprises an organic anti-reflection coating (organic ARC), an inorganic anti-reflection coating (inorganic ARC), a dielectric anti-reflection coating (dielectric ARC), a plasma enhanced anti-reflective layer (PEARL), or a combination thereof.

3. The method as claimed in claim 1, wherein the anti-reflect layer is formed by deposition or spin coating.

4. The method as claimed in claim 1, wherein the anti-reflect layer is a bottom anti-reflect layer (BARC).

5. The method as claimed in claim 1, wherein parts of the anti-reflect layer are removed by edge cleaning.

6. The method as claimed in claim 1, wherein the photoresist layer is formed by spin coating.

7. A structure for preventing wafer edge defocus, comprising:
a wafer;
an anti-reflect layer, installed on parts of the wafer such that the rim of the wafer is exposed; and
a photoresist layer blanketing the anti-reflect layer and the rim of the wafer.

8. The method as claimed in claim 7, wherein the anti-reflect layer comprises an organic anti-reflection coating (organic ARC), an inorganic anti-reflection coating (inorganic ARC), a dielectric anti-reflection coating (dielectric ARC), a plasma enhanced anti-reflective layer (PEARL), or a combination thereof.

9. The method as claimed in claim 7, wherein the anti-reflect layer is formed by deposition or spin coating.

10. The method as claimed in claim 7, wherein the anti-reflect layer is a bottom anti-reflect layer (BARC).

11. The method as claimed in claim 7, wherein parts of the anti-reflect layer are removed by edge cleaning.

12. The method as claimed in claim 7, wherein the photoresist layer is formed by spin coating.
